(19) United States
(12) Patent Application Publication
(10) Pub. No.: US 2013/0335011 A1
(43) Pub. Date: Dec. 19, 2013

(54) MICROELECTRONIC DEVICES FOR HARVESTING KINETIC ENERGY AND/OR DETECTING MOTION, AND ASSOCIATED SYSTEMS AND METHODS

(71) Applicant: Ruamoko MEMS, Inc., Durham, NC (US)

(72) Inventors: Karl Böhringer, Seattle, WA (US); John Reif, Durham, NC (US)

(21) Appl. No.: 13/910,979

(22) Filed: Jun. 5, 2013

Related U.S. Application Data
(60) Provisional application No. 61/656,425, filed on Jun. 6, 2012.

(51) Int. Cl. H02N 11/00; B81C 3/00

(52) U.S. Cl. CPC H02N 11/002; B81C 3/00
USPC 320/107; 310/300; 29/831

(57) ABSTRACT

Microelectronic devices for harvesting kinetic energy and/or detecting motion, and associated systems and methods. Particular embodiments include an energy harvesting device for generating electrical energy for use by microelectronic devices, where the energy harvesting device converts to electrical energy the kinetic energy among or within the microelectronic devices and their packaging, and provides this electrical energy to power the microelectronic devices.

### CROSS-REFERENCE TO RELATED APPLICATION

The present application claims priority to U.S. Provisional Application No. 61/656,425, filed on Jun. 6, 2012 and incorporated herein by reference.

### TECHNICAL FIELD

The present technology relates to microelectronic devices for harvesting kinetic energy, converting the kinetic energy to electrical energy for use by the same and/or other microelectronic devices, and/or detecting motion.

### BACKGROUND

Microelectronic devices, including MEMS devices (micro-electro-mechanical systems) and other devices that include semiconductor chips, are used for a wide variety of applications, including sensing, actuation, communication, control, computation, and combinations of these applications. These devices are increasingly being positioned in remote or inconvenient locations (such as embedded into buildings, machines and human bodies) where power is difficult or impossible to deliver. Examples of these devices include wireless sensor networks and embedded control MEMS devices such as tire pressure sensors or intraocular pressure sensors.

When these microelectronic devices are active, they may require power roughly ranging from hundreds of microwatts to a few milliwatts, but they typically are active and require significant power for only a small fraction (typically at most 2%) of the time, and otherwise, when inactive require a much smaller power level. Hence, the average electrical power requirements for such devices often range between tens to hundreds of microwatts.

While batteries can be supplied for these microelectronic devices, this entails an increase in system mass and size, and limitations in duration of energy supply, unless the batteries are only used during high demand active periods, and are otherwise recharged via some form of energy harvesting. Accordingly, there remains a need in the industry for techniques that efficiently supply energy to microelectronic devices.

### BRIEF DESCRIPTION OF THE DRAWINGS

FIG. 1 is a partially schematic, cross-sectional illustration of a system having a microelectronic device coupled to a support member via a flexible connection that supports electrical power harvesting in accordance with an embodiment of the disclosure.

FIG. 2A is a partially schematic, cross-sectional illustration of a system that includes a flexible connection and an electromagnetic power generator configured in accordance with an embodiment of the disclosure.

FIG. 2B is a partially schematic, partially exploded top view of an embodiment of the system shown in FIG. 2A.

FIG. 3A is a partially schematic, cross-sectional side view of a system having a flexible connection and an electrostatic power generator configured in accordance with another embodiment of the disclosure.

FIG. 3B is a partially schematic, partially exploded top view of an embodiment of the system shown in FIG. 3A.

FIG. 4A is a partially schematic, cross-sectional side view of a system having a flexible connection and a piezoelectric generator configured in accordance with an embodiment of the disclosure.

FIG. 4B is a partially schematic, partially exploded top view of an embodiment of the system shown in FIG. 4A.

FIG. 5 is a partially schematic, cross-sectional side view of a system that includes a spiral piezoelectric generator configured in accordance with another embodiment of the disclosure.

FIG. 6A is a partially schematic, cross-sectional side view of a system that includes a magnetostrictive electrical power generator configured in accordance with an embodiment of the disclosure.

FIG. 6B is a partially schematic, partially exploded top view of an embodiment of the system shown in FIG. 6A.

FIG. 7A is a partially schematic, cross-sectional side view of a system that includes a microelectronic device with a packaged component, that may be a MEMS device or a semiconductor chip, configured in accordance with still another embodiment of the disclosure.

FIG. 7B is a partially schematic, cross-sectional side view of a system that includes a microelectronic device with multiple stacked components, that may be semiconductor chips or MEMS devices, configured in accordance with still another embodiment of the disclosure.

FIG. 8 is a partially schematic, cross-sectional side view of a system that includes a liquid-containing flexible connection and a turbine-driven generator in accordance with an embodiment of the disclosure.

FIG. 9 is a partially schematic, cross-sectional side view of a system having a liquid-containing flexible connection and an ionic membrane configured in accordance with an embodiment of the disclosure.

FIG. 10 is a partially schematic, cross-sectional side view of a system having a liquid-containing flexible connection and an associated piezoelectric member configured in accordance with still another embodiment of the disclosure.

FIG. 11 is a partially schematic, cross-sectional illustration of a battery pack system that includes features for harvesting energy in accordance with embodiments of the present technology.

FIG. 12A is a partially schematic, cross-sectional illustration of an accelerometer system having a proof mass in accordance with a conventional arrangement.

FIGS. 12B-12D are partially schematic, cross-sectional illustrations of accelerometer systems arranged in accordance with several embodiments of the present technology.

### DETAILED DESCRIPTION

The present technology is directed generally to harvesting kinetic energy and sensing motion. Particular aspects of the technology relate to harvesting vibration energy from microelectronic devices that are already configured to perform another function. Accordingly, the technology includes harvesting kinetic energy from existing functional structures, rather than adding structures whose sole purpose is to provide a vibrating mass from which energy is extracted. Several embodiments are described below in the context of harvesting vibration energy. Additional embodiments can include harvesting other types of kinetic energy that are not necessarily vibrational in nature.

Vibration energy is available to MEMS and other microelectronic devices embedded into buildings, machines, vehicles, human bodies and other locations. Typically, in these locations, the available vibration power occurs mostly in frequency ranges of tens to thousands of Hz and the power levels available for conversion to electrical power is often at least hundreds of microwatts up to milliwatts.

A key challenge in the microelectronic device industry is the delivery of electrical power to microelectronic devices by harvesting energy from sources in their vicinity. Potential energy sources, in addition to batteries, include thermal differentials or gradients, electromagnetic energy such as radio frequency energy, solar energy and other light sources, fluid flow, and vibration energy. Many of these energy sources are available only over limited time ranges (e.g., solar energy), and/or are difficult to harvest at the scale of microelectronic devices.

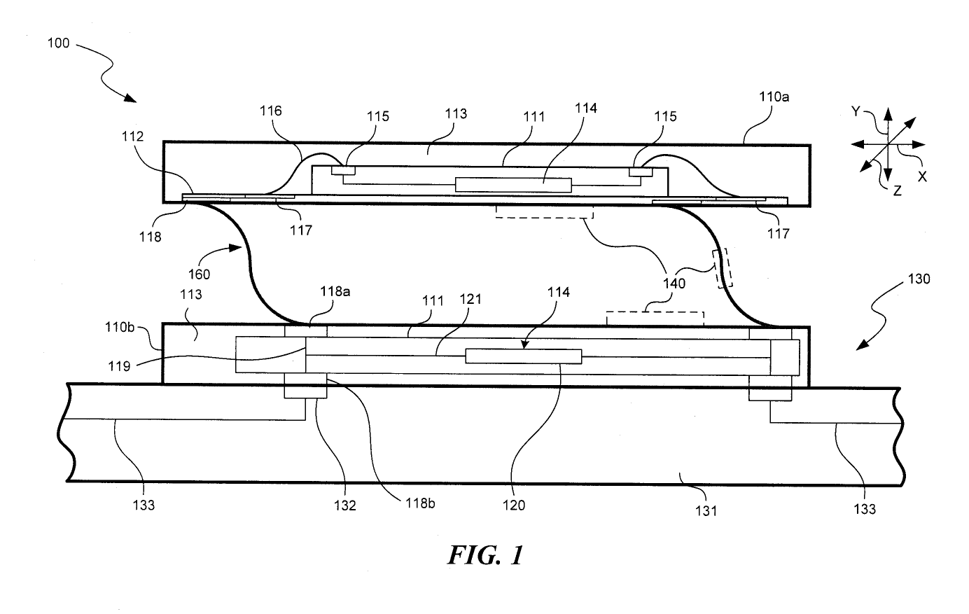

The present disclosure and associated technologies are directed generally to microelectronic devices for harvesting vibrational energy and/or other forms of kinetic energy, and associated systems and methods. In particular embodiments, the systems include microelectronic devices (e.g., bare or packaged chips) that are connected to a support structure with a flexible link. As the microelectronic device vibrates and/or undergoes other motion relative to the support structure during normal use, it generates energy which is captured by the system and returned to the microelectronic device to power functional elements of the device, or stored, or directed elsewhere. The functional elements of the microelectronic device can include, for example, a memory, a processor, a sensor, or other microelectronic-based structures. Several details describing structures and processes that are well-known and often associated with MEMS and other microelectronic devices are not set forth in the following description to avoid obscuring other aspects of the disclosure. Moreover, although the following disclosure sets forth several embodiments, several other embodiments can have different configurations, arrangements, and/or components than those described in this section. In particular, other embodiments may have additional elements, and/or may lack one or more of the elements described below with reference to FIGS. 1-12D.

The present technology includes an energy harvesting device for generating electrical energy for use by MEMS and/or other microelectronic devices. The technology exploits the fact that the available harvestable vibration energy grows in proportion to the total mass experiencing the vibrations. Aspects of the technology disclosed herein advance the current state of the art by making use of much of the entire masses of the MEMS devices and their packaging to collect vibration energy; in particular, the harvesting device converts to electrical energy the vibration energy among or within microelectronic devices and their packaging. The present technology accordingly exploits the fact that the total masses of the MEMS and/or other microelectronic devices and their packaging are typically far larger than just the masses of the micro-engineered components of the devices. In contrast, existing techniques either integrate micro-engineered energy harvesting devices into the microelectronic devices, or require additional masses (beyond the microelectronic device and packaging) that harvest the vibration energy.

Particular embodiments described in greater detail below include:
Electromagnetic generators, in which vibrations cause relative mechanical movements between magnets and an electrical coil, which induce a change in magnetic flux that drives, by Faraday's law of induction, a current in the coil of wire;
Electrostatic generators, in which vibrations cause relative mechanical movements between charged parts, such as, but not limited to electrets, which induce currents in wires connected to the charged parts;
Piezoelectric generators, in which vibrations cause mechanical movements, which induce time-varying elastic strain in a piezoelectric material (e.g., on a cantilever beam), producing a time-varying electric field in that material, providing an electrical current;
Magnetostrictive generators, in which vibrations cause mechanical movements, which induce time-varying elastic strain in a magnetostrictive material in the presence of an electrical coil, producing a time-varying magnetic field in that material, providing an electrical current in the coil; and
Fluid flow generators, in which vibrations cause fluid movements, which are transduced to provide an electrical current. The directed flow may be used to harvest energy, for example air flow in air-conditioning systems or blood flow inside the body. The source of flow may either be vibration or vibration can be caused by fluid flow.

In many of the devices described both above and below, individual features of the devices, or the entire devices, can be formed using photolithography, printing techniques, and/or other manufacturing techniques often used to process microelectronic devices.

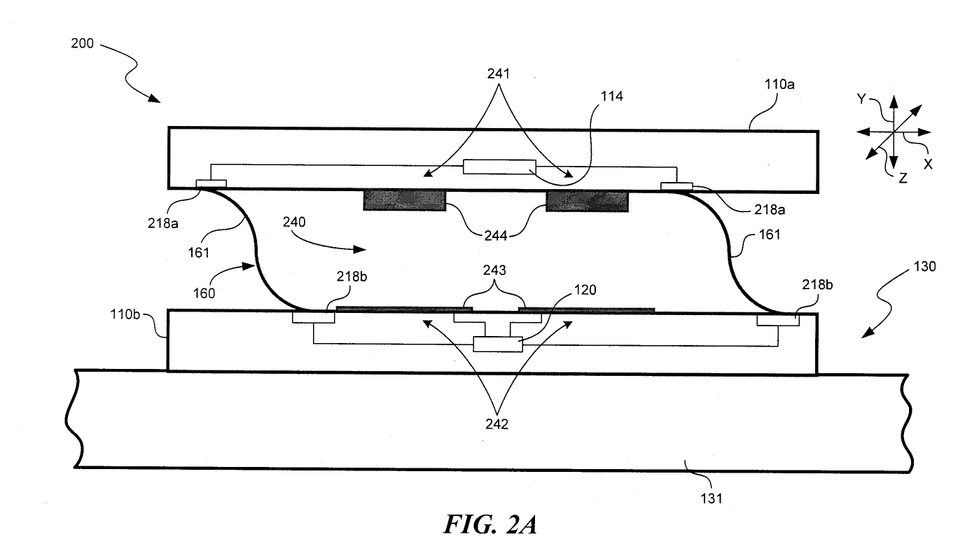

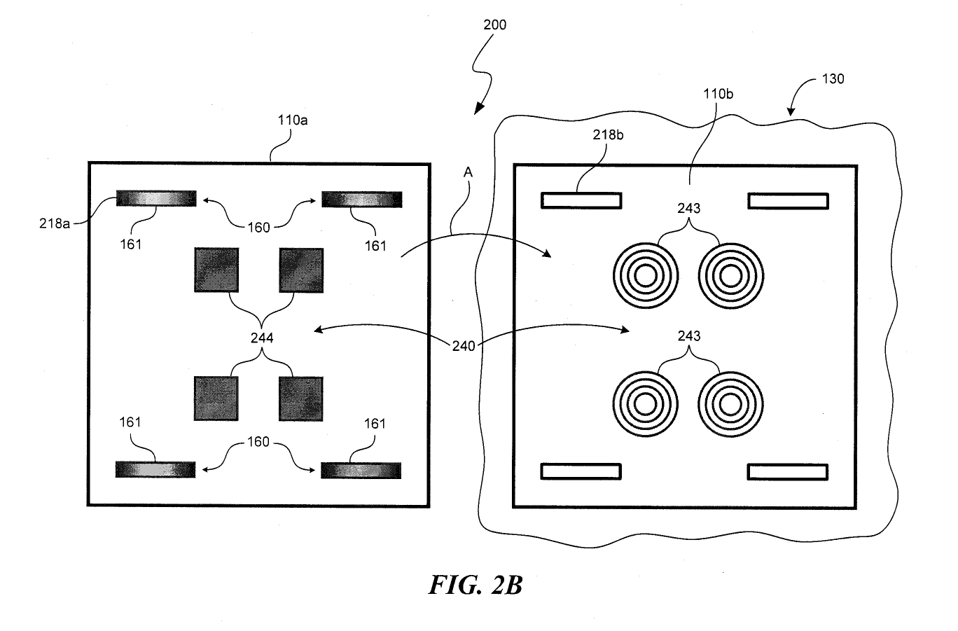

FIG. 1 is a partially schematic, cross-sectional illustration of a system 100 that includes a microelectronic device (e.g., a first microelectronic device 110a) connected to a support member 130 via a flexible connection 160. The system 100 further includes an electrical power generator 140 having elements carried by the first microelectronic device 110a, the flexible connection 160, and/or the support member 130. The electrical power generator 140 captures energy produced by the relative motion (e.g., vibration motion) between the first microelectronic device 110a and the support member 130 and/or other elements of a microelectronic device package that supports, carries or encloses the microelectronic device 110a. The relative motion can include vibration motion that results when the system 100 (in particular, the first microelectronic device 110a) is operated during normal use to provide a function other than generating energy. Such functions can include functions typical of microelectronic devices and their semiconductor chip components, e.g., memory functions, processor functions, sensor functions and/or lower or higher level functions. The energy harvested by the system 100 is then conditioned (e.g., at the support member 130) and provided back to the first microelectronic device 110a to power an electrically-driven process carried out by the first microelectronic device 110a. Further aspects of this general arrangement are described below with reference to FIG. 1. Systems having a variety of flexible connections and associated electrical power generators are then further described with reference to FIGS. 2A-10.

In particular embodiments, the first microelectronic device 110a can include an existing, off-the-shelf packaged semiconductor chip, for example, a packaged memory chip, processor chip, sensor chip or another type of chip that provides a functionality aside from generating energy during normal operation. Accordingly, the first microelectronic device 110a can include a die 111 having an active element 114, carried by a package substrate 112, and encapsulated in a packaging material 113. The active element 114 is connected to die bond pads 115, which are in turn connected to substrate bond pads 117 with a die connector 116. The die connector 116 can include a wire bond or other suitable conductive element (e.g., solder balls). The substrate bond pads 117 are in turn connected to package bond pads 118 that facilitate electrical communication to and from the active element 114.

The first microelectronic device 110a can include any one or more of the following structures: micro-scale devices (e.g., devices with a size scale roughly between tens of microns to tens of millimeters per side), which can in turn include functional structures or sub-structures ranging in size from about 0.1 micron to about 10 mm; microelectronic components (e.g., micro-scale devices that have electronic functionality, which can include electronic circuit chips, multi-chip modules, including their packaging, and other electronic components such as capacitors and batteries); micromechanical components (e.g., micro-scale devices that have mechanical functionality); micro-electro-mechanical components (e.g., micro-scale devices that have a combination (one or both) of electronic and mechanical functionality); and MEMS devices (e.g., micro-scale devices that include combinations of one or more microelectronic and micromechanical components, or are exclusively combinations of one or more microelectronic components, or are exclusively combinations of one or more micromechanical components). As described above, the first microelectronic device 110a can be an off-the-shelf component, and accordingly need not be adapted, retrofitted or otherwise modified to receive power produced by its motion.

The flexible connection 160 can allow the first microelectronic device 110a to move with respect to the support member 130 with one or more degrees of freedom relative to one or more axes. For example, the first microelectronic device 110a can move from side to side (in the X direction), and/or up and down (e.g., in the Y direction) and/or into and out of the plane of FIG. 1 (in the Z direction), relative to the support member 130. For purposes of illustration, the X, Y and Z axes are shown in FIG. 1 and other Figures in a perspective view. In at least some embodiments, the first microelectronic device 110a can also twist, pivot or rotate about any of the foregoing axes. The flexible connection 160 can allow a predetermined amount of motion between the first microelectronic device 110a and the support member 130 relative to one or more of the foregoing axes, and can constrain the relative motion to prevent damage to the overall system 100. In particular embodiments, the flexible connection 160 can be selected to produce a resonant frequency for relative motion of the first microelectronic device 110a that is at or close to the frequency of the external vibration that the system 100 is expected to encounter. This arrangement can increase the power extracted by the system 100, and can include appropriate damping or other stops to prevent excessive motion. The electrical power generator 140 collects energy resulting from the relative motion, and the support member 130 can condition the energy before providing the energy back to the first microelectronic device 110a. This is unlike conventional implementations of flexible interconnects, which are instead used to reduce stress due and damage to thermal mismatch between components of multi-chip modules.

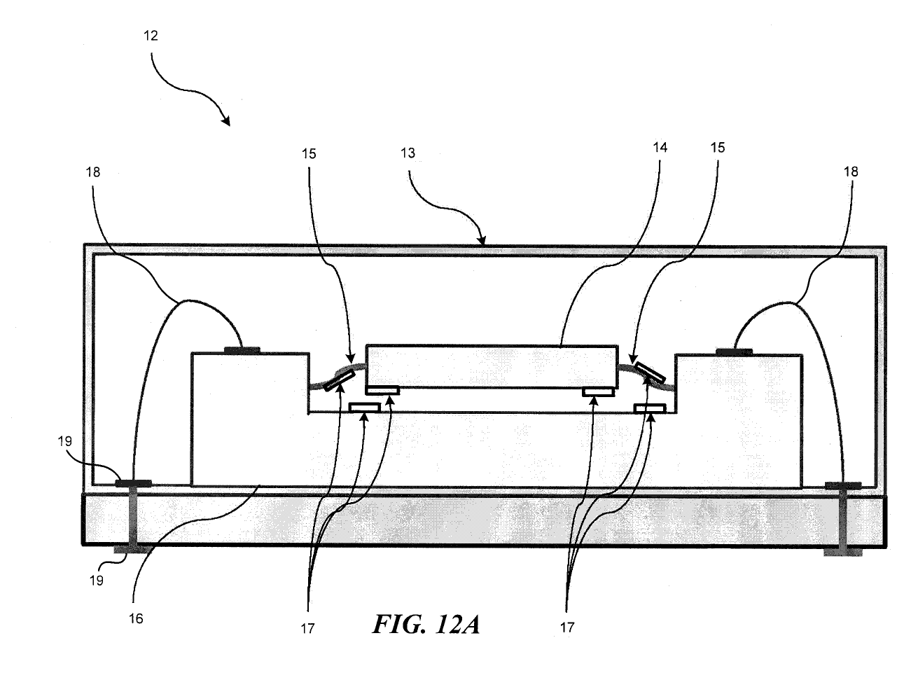

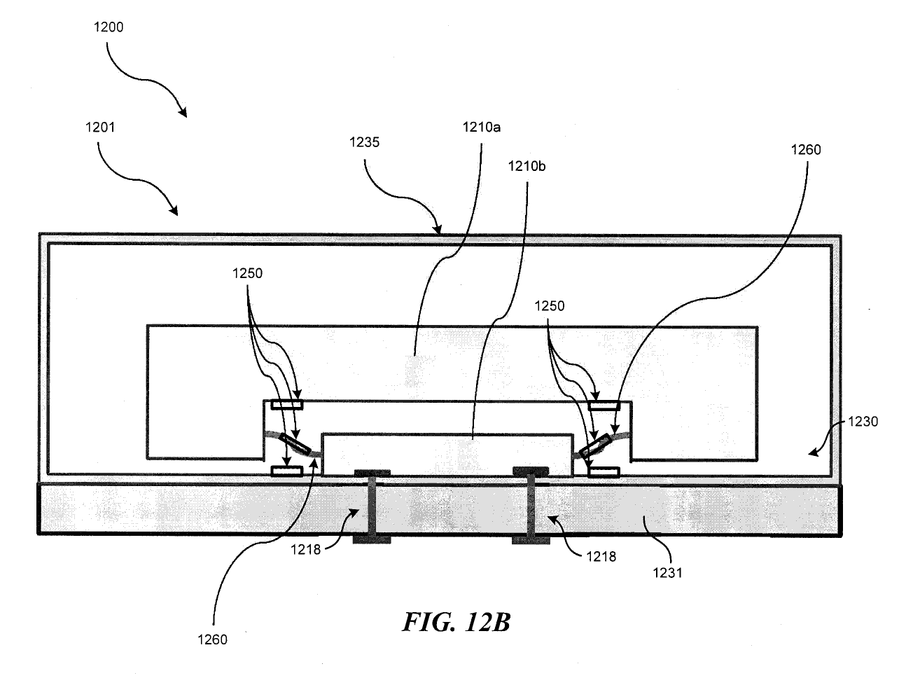

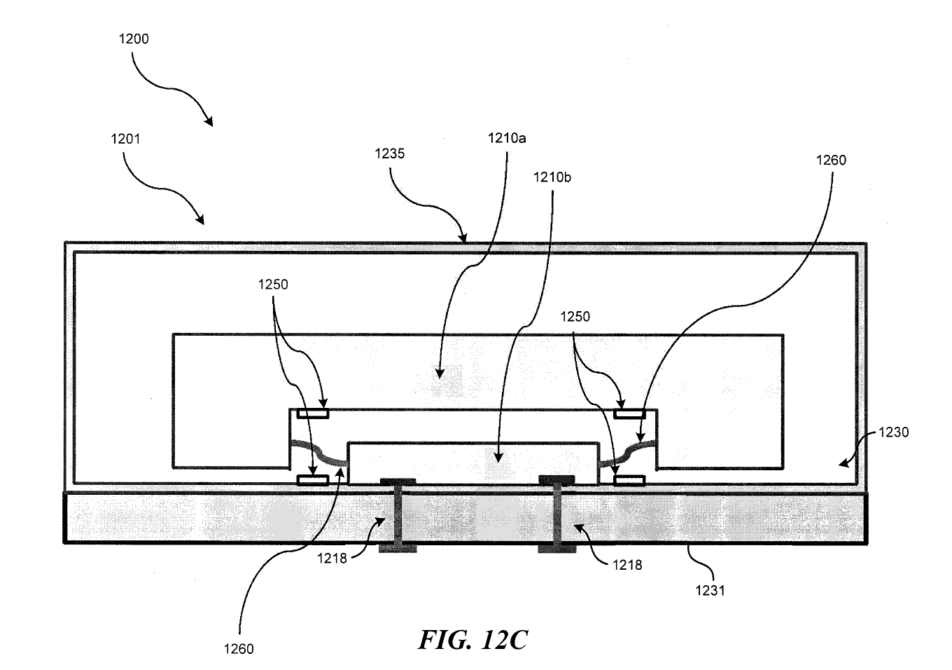

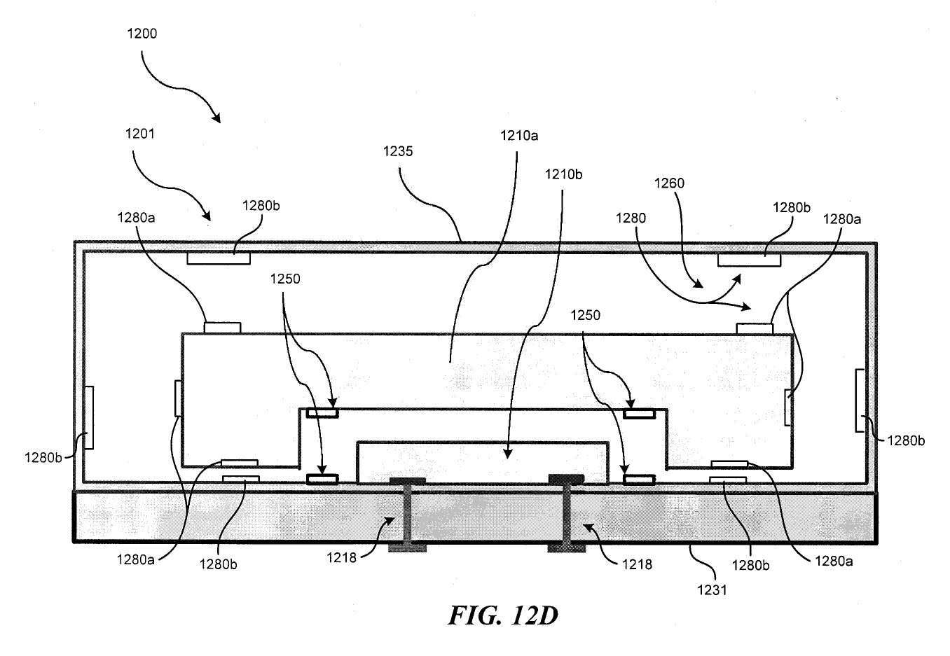

The flexible connection 160 can have one or more of several suitable arrangements. For example, the flexible connection 160 can include a flexible metal strip, formed by using photolithography or other techniques. Accordingly, the flexible connection 160 can provide physical contact with both the support member 130 and the first microelectronic device 110a. In other embodiments, the flexible connection 160 can include a pair of opposing magnets that allow relative movement between the support member 130 and the first microelectronic device 110a without providing a direct mechanical connection. In such instances, the motion of the first microelectronic device 110a relative to the support member 130 can be constrained by sidewalls, fences and/or other structures (not shown in FIG. 1). A representative arrangement is described in further detail below with reference to FIG. 12D.

In a particular embodiment, the support member 130 includes a support member substrate 131 (e.g., a printed circuit board or other suitable structure), which in turn carries a signal conditioning element 120. The signal conditioning element 120 can be an active element 114 of a second microelectronic device 110b. In other embodiments, the signal conditioning element 120 can be housed in or otherwise carried by the support member 130 without the second microelectronic device 110b. In either embodiment, the signal conditioning element 120 can include rectifiers, transformers and/or other components suitable for receiving input power and providing the power in a more stable, uniform, and/or otherwise system-compatible format. In an embodiment illustrated in FIG. 1, the signal conditioning element 120 is carried by a die 111 that is encapsulated in a packaging material 113. The signal conditioning element 120 communicates with structures outside the second microelectronic device 110b via first and second package bond pads 118a, 118b. Accordingly, the second microelectronic device 110b can include bond pads 132, lines 121 and/or vias 119 that provide the requisite signal and power paths. The support member substrate 131 can also include support member lines 133 that conduct signals to and/or from the first and second microelectronic devices 110a, 110b. Accordingly, signals and/or power can be conveyed among the first microelectronic device 110a, the support member 130, and external devices (not shown in FIG. 1).

FIG. 2A is a partially schematic, cross-sectional side view of a system 200 that includes a first microelectronic device 110a carried by a support member 130 via a flexible connection 160. The flexible connection 160 can include multiple electrically conductive, metallic microsprings or other conductors 161 that can be manufactured as part of the microelectronic manufacturing process used for the first microelectronic device 110a and/or the support member 130. Accordingly, the conductors 161 forming the flexible connection 160 can both allow relative movement between the first microelectronic device 110a and the support member 130, and transmit data signals and/or power between these two components. Representative techniques for forming these devices are disclosed in two articles by Shubin, et al., one titled “A Package Demonstration With Solder Free Compliant Flexible Interconnects” (2010), the other titled “Novel Packaging With Rematable Spring Interconnect Chips for MCM” (2009), both of which are incorporated herein by reference. To the extent that the present disclosure of the technology conflicts with any materials incorporated herein by reference, the present disclosure controls.

The system 200 further includes an electrical power generator 240 having components carried by both the first microelectronic device 110a and the support member 130. For example, the electrical power generator 240 can include one or more first elements 241 (e.g. magnets 244) carried by the first microelectronic device 110a, and one or more second elements 242 (e.g. coils 243) carried by the support member 130. The flexible connection 160 can allow the first microelectronic device 110a to move (e.g., translationally and/or rotationally) relative to the support member 130 relative to any one or more of the X, Y and Z axes shown in FIG. 2A. The electromagnetic energy created by the relative movement between the magnets 244 and the coils 243 creates an electrical current at the support member 130 that is conditioned by the signal conditioning element 120, and then provided to the first microelectronic device 110a via one or more of the conductors 161. Accordingly, one or more of the conductors 161 can provide power back to the first microelectronic device 110a, and others of the conductors 161 can provide data signals between the first microelectronic device 110a and support member 130. The conductors 161 can be connected between a first package bond pad 218a at the first microelectronic device 110a, and a second package bond pad 218b at the support member 130. In a particular embodiment, the conductors 161 can be formed integrally with the second package bond pads 218b.

FIG. 2B is a partially exploded, top plan view of an embodiment of the system 200 shown in FIG. 2A. For purposes of illustration, the first microelectronic device 110a is shown inverted (e.g., face up) to illustrate the features on the underside of the first microelectronic device 110a. During manufacturing, the first microelectronic device 110a is placed face down on the support member 130, as indicated by arrow A to attach the flexible connection 160 between these two components. The flexible connection 160 can be attached by soldering or other suitable techniques known to those of ordinary skill in the art, and can initially connect to the support member 130 (in a typical installation) or the first microelectronic device 110a. In a particular embodiment shown in FIG. 2B, the flexible connection 160 includes four spaced-apart conductors 161. In other embodiments, the flexible connection 160 can include more or fewer conductors 161. In further embodiments, each conductor 161 can include multiple, independently addressable conductive elements so as to provide multiple signal and/or power channels at a particular connection location.

As is also shown in FIG. 2B, the electrical power generator 240 can include four magnets 244 carried by the first microelectronic device 110a, and four corresponding coils 243 carried by the support member 130. In other embodiments, the electrical power generator 240 can include other numbers and/or arrangements of magnets 244 and coils 243. Both the magnets 244 and the coils 243 can be formed using techniques generally similar to those used for standard microelectronic processing, e.g., standard material deposition techniques and standard photolithographic, etching, and/or other material removal techniques.

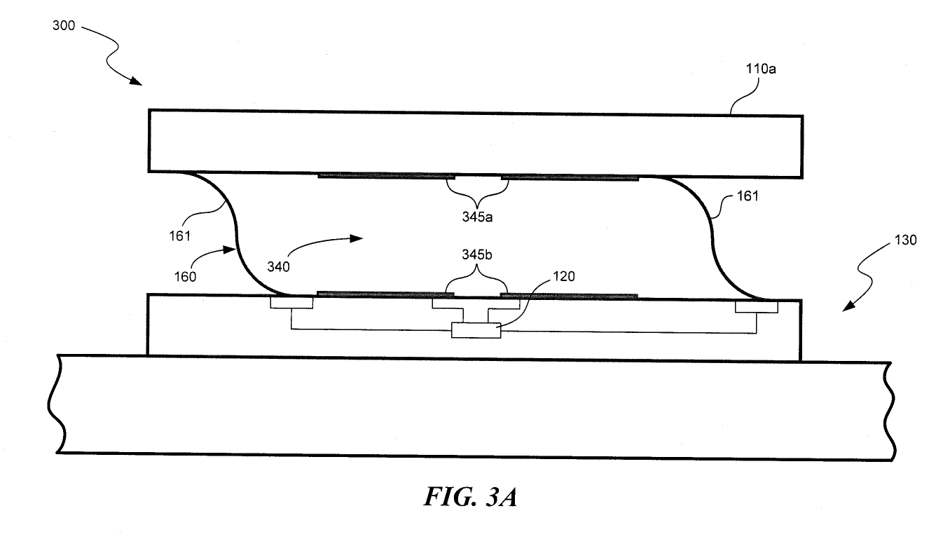

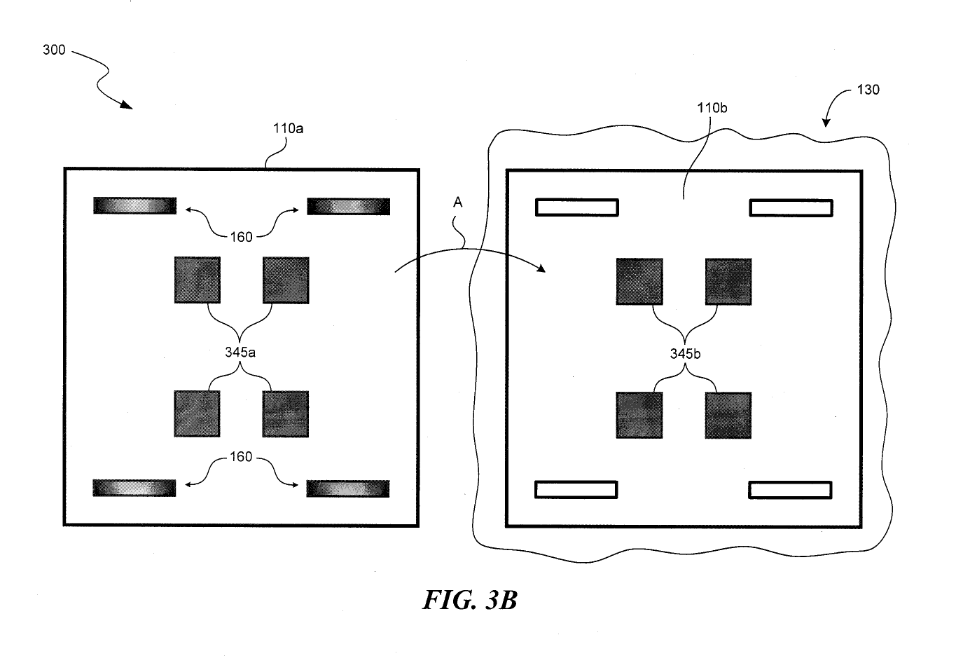

FIG. 3A is a partially schematic, cross-sectional side view of a system 300 that includes a flexible connection 160 and conductors 161 generally similar to those described above with reference to FIGS. 2A-2B, and an electrical power generator 340 configured in accordance with another embodiment of the disclosure. In one aspect of this embodiment, the electrical power generator 340 includes one or more first capacitor plates 345a carried by the first microelectronic device 110a, and one or more corresponding second capacitor plates 345b carried by the support member 130. During operation, an initial charge can be placed on both the first capacitor plates 345a and the second capacitor plates 345b. In other embodiments, electrets are placed near the capacitor plates so that relative motion between the plates induces moving charges in the plates. As the first microelectronic device 110a moves relative to the support member 130, the motion of the charged capacitor plates 345a, 345b relative to each other generates an electrical current that is harvested at the support member 130, conditioned by the signal conditioning element 120, and directed back to the first microelectronic device 110a via one or more of the conductors 161. The capacitor plates 345a, 345b can be formed at the first microelectronic device 110a and at the support member 130 using existing microelectronic processing techniques, for example, techniques generally similar to those used to form capacitor elements, bond pads and/or conductive lines in conventional microelectronic devices.

FIG. 3B is a partially exploded, top plan view of the system 300 illustrating the underside of the first microelectronic device 110a, along with the upper surfaces of the support member 130. In a representative embodiment, the first microelectronic device 110a includes four first capacitor plates 345a, and the support member 130 includes four corresponding second capacitor plates 345b. In other embodiments, the number of capacitor plates, the shapes of the capacitor plates, the arrangement of the capacitor plates, and/or the relative sizes of the capacitor plates can be different than in the representative arrangement shown in FIG. 3B.

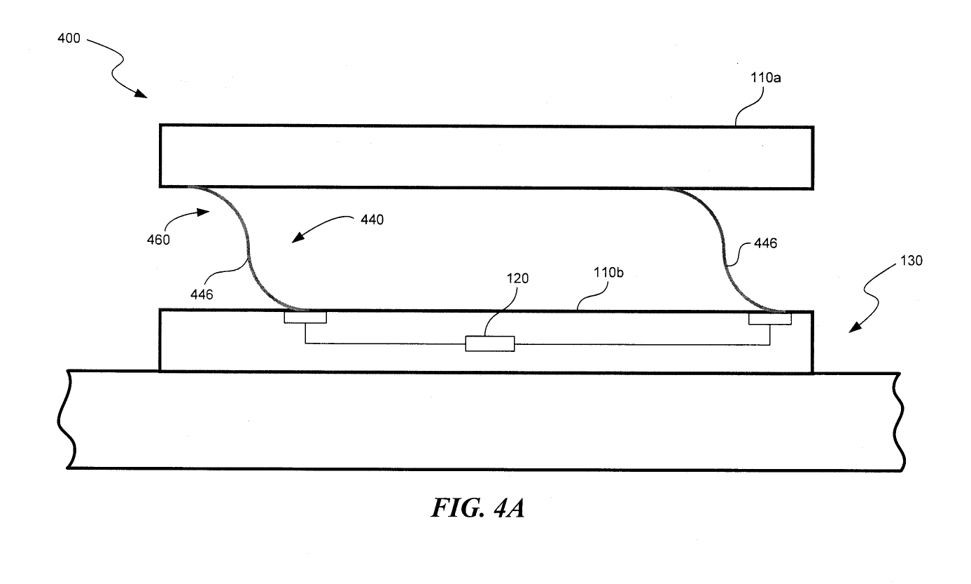

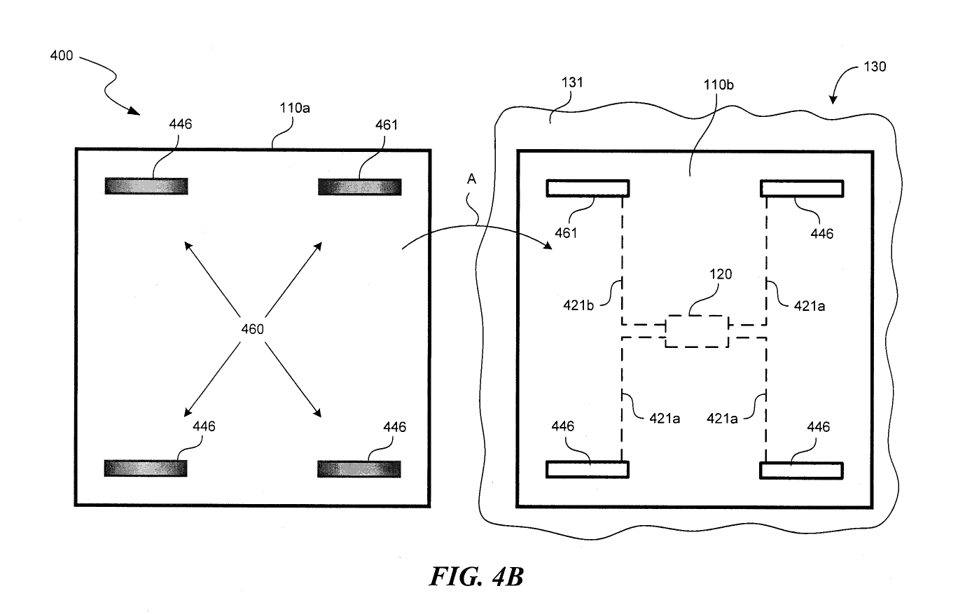

FIG. 4A is a partially schematic, cross-sectional side view of a system 400 having an electrical power generator 440 that includes a flexible connection 460 configured in accordance with another embodiment of the disclosure. In this embodiment, the flexible connection 460 includes one or more piezoelectric members 446 connected between the first microelectronic device 110a and the support member 130. The piezoelectric members 446 include a piezoelectric material (e.g. aluminum nitride or another suitable material) that generates an electrical current when placed under loads that cause a strain or other mechanical deformation of the piezoelectric members 446. The electrical current generated by the mechanical deformation of the piezoelectric members 446 is collected at the support member 130, provided to the signal conditioning element 120, and then redirected to the first microelectronic device 110a to power the active elements at the first microelectronic device 110a.

FIG. 4B is a partially schematic, partially exploded top view of the lower surface of the first microelectronic device 110a and the upper surfaces of the support member 130. In a representative embodiment, the flexible connection 460 includes three piezoelectric members 466, and one conductor 461. The piezoelectric members 446 generate electrical power in the manner described above, and provide the power to the signal conditioning element 120 via first lines 421a. The signal conditioning element 120 can provide conditioned power to the conductor 461 via second lines 421b. The conductor 461 can include multiple, independently addressable conductive elements that direct data signals back and forth between the support member 130 and the first microelectronic device 110a, and provide power from the signal conditioning element 120 (carried by the support member 130) to the first microelectronic device 110a. In other embodiments, the system 400 can include other numbers of piezoelectric members 446 and/or other conductor arrangements.

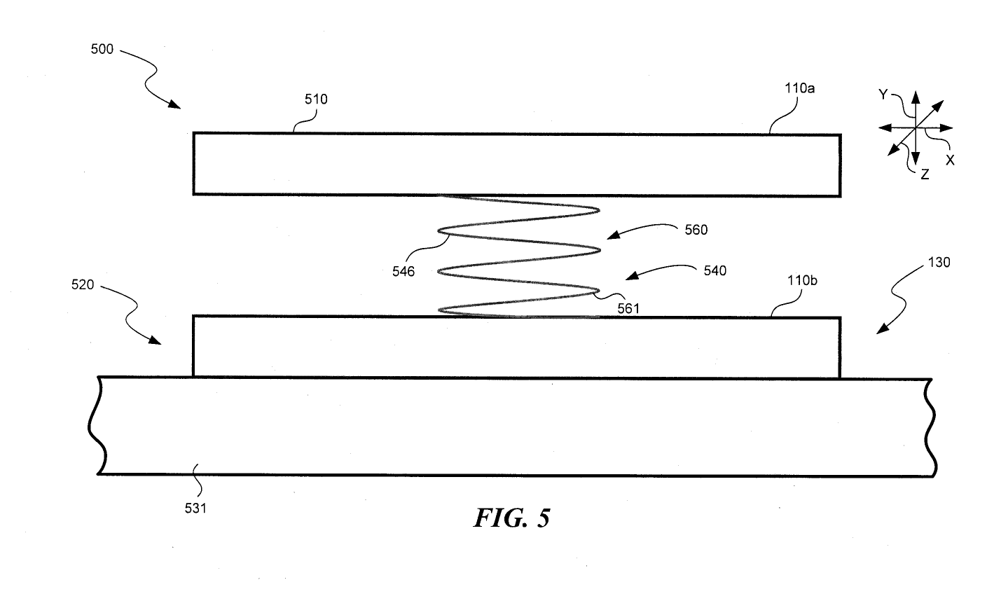

FIG. 5 is a partially schematic, cross-sectional side view of a system 500 that includes an electrical power generator 540 and a flexible connection 560 configured in accordance with yet another embodiment of the disclosure. In one aspect of this embodiment, a generally spiral-shaped piezoelectric member 546 provides the function of both the flexible connection 560 and the electrical power generator 540. Accordingly, the piezoelectric member 546 generates electrical power that is directed to the support member 130, and facilitates (while also constraining) relative motion between the first microelectronic device 110a and the support member 130. This motion can include rotational degrees of freedom (e.g. rotation about the Y axis, the X axis and/or the Z axis). Accordingly, the spiral-shaped piezoelectric member 546 can capture additional energy compared with at least some of the foregoing embodiments. In a further particular embodiment, the piezoelectric member 546 can include conductors 561 co-located in the same structure, but electrically isolated from the piezoelectric member 546 itself. Accordingly, the same structure can be used to provide data signals back and forth between the first microelectronic device 110a and the support member 130, while also directing harvested energy to the first microelectronic device 110a. In other embodiments, separate structures can provide these functions. Such structures can have a leaf-spring configuration (e.g. generally similar to those discussed above with reference to FIGS. 2A-4B), or another configuration (e.g., a spiral shape). The particular arrangement selected for embodiments of the system 500 can be selected in a manner that balances the versatility of independent structures that generate electrical energy and transmit power and data signals, against the potential that the additional structures will inhibit the rotational motion facilitated by the spiral-shaped piezoelectric member 546.

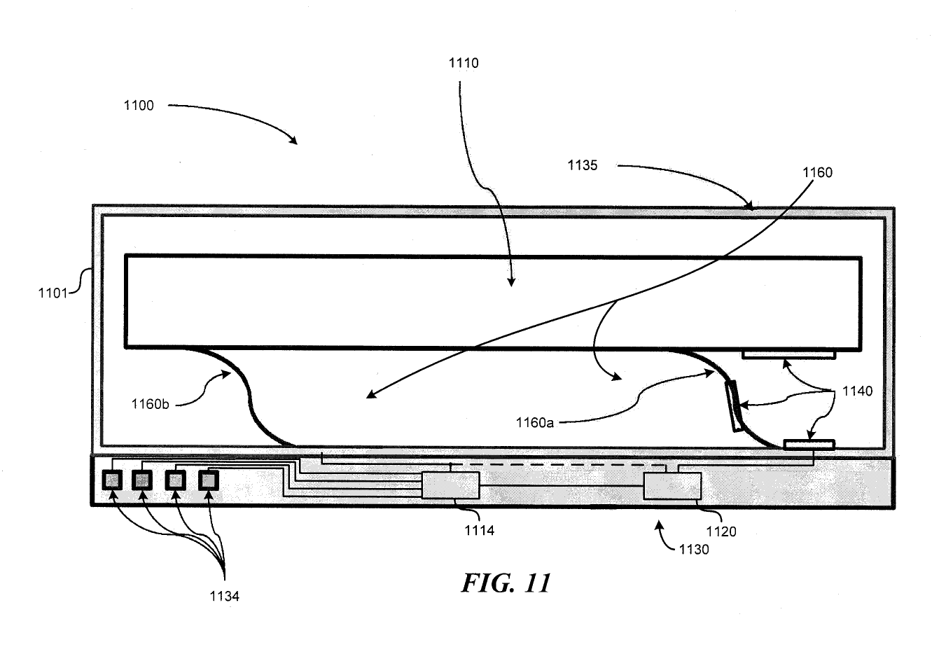

In another embodiment, the system 500 can include a battery in combination with a microelectronic structure. For example, the first microelectronic device 110a can be replaced with a battery 510 (shown schematically in FIG. 5) that is connected to a microelectronic structure 520 with the flexible connection 560. The microelectronic structure 520 can include the second microelectronic device 110b (e.g., a semiconductor chip) and, optionally, a support member 130 (e.g., a support member substrate 131). Accordingly, the electrical power generator 540 can generate electrical power based on the relative motion between the battery 510 and the microelectronic structure 520. The electrical power generator 540 (or components of the electrical power generator 540) can be carried by the battery 510, the flexible connection 560, and/or the support member 130. In this manner the system 500 can harvest energy resulting from the relative movement of the battery 510. Because the battery 510 can often have a significant mass, the power extracted from its movement can be significant as well. While the foregoing arrangement for harvesting energy from the motion on the battery 510 is described in the context of a piezoelectric member 546, similar arrangements can be used in combination with any of the other electrical power generators described herein in other embodiments. In still further embodiments, the battery can form a portion of a battery package, for example, as described further below with reference to FIG. 11.

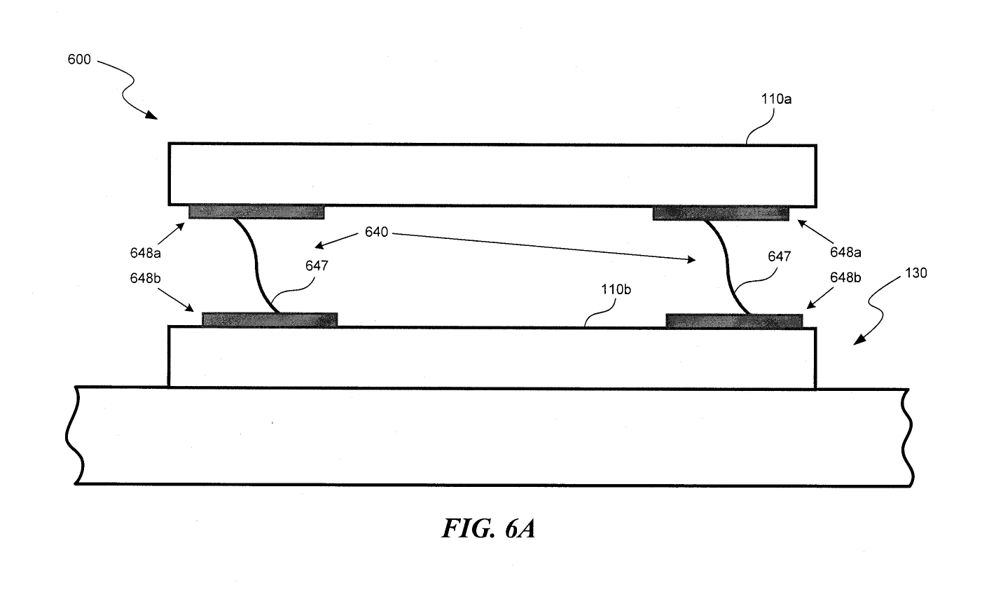

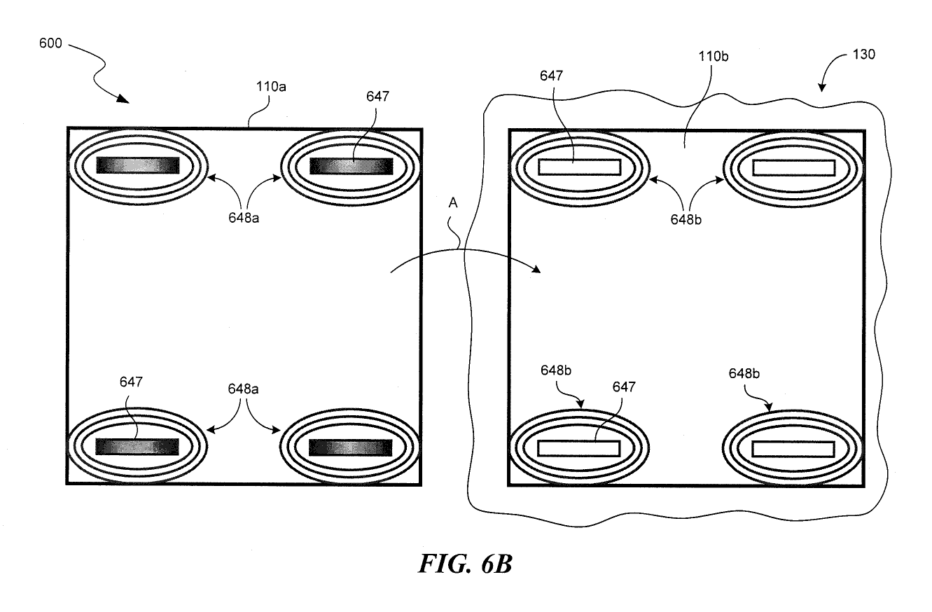

FIG. 6A is a partially schematic, cross-sectional side view of a system 600 that includes an electrical power generator 640 configured to harvest electrical energy via a magnetostrictive effect. Accordingly, the electrical power generator 640 can include one or more magnetostrictive members 647 and one or more corresponding induction coils 648. In an embodiment shown in FIG. 6A, the induction coils 648 include first induction coils 648a located at the first microelectronic device 110a and second induction coils 648b located at the support member 130. Accordingly, energy harvested by the electrical power generator 640 at the first induction coils 648a can either be conditioned at the first microelectronic device 110a or directed (e.g. via one or more conductors) to the support member 130 for conditioning, and then directed back to the first microelectronic device 110a. In other embodiments, the first induction coils 648a at the first microelectronic device 110a can be eliminated, and the electrical energy can be generated solely at the second induction coils 648b located at the support member 130. In any of these embodiments, the electrical power is generated by virtue of a change in magnetization of the magnetostrictive member 647 when placed under stress induced by the relative motion between the first microelectronic device 110a and the support member 130 (e.g. the Villari effect). The changing magnetic field can induce a current in the induction coils 648a, 648b, which is then conditioned and provided to the first microelectronic device 110a in accordance with any of the techniques described above.

FIG. 6B is a partially schematic, partially exploded top plan view of the system 600 illustrating the lower surface of the first microelectronic device 110a and the upper surfaces of the support member 130. In this representative embodiment, each of the magnetostrictive members 647 is positioned within a corresponding one of the induction coils 648a, 648b (schematically represented by concentric circles in FIG. 6B). In other embodiments, the relationship between the magnetostrictive member 647 and the induction coils 648a, 648b can be different. In any of these embodiments, separate conductors (not shown in FIG. 6B) can provide power and data signals between the first microelectronic device 110a and support member 130, generally in the manner described above with reference to the preceding embodiments.

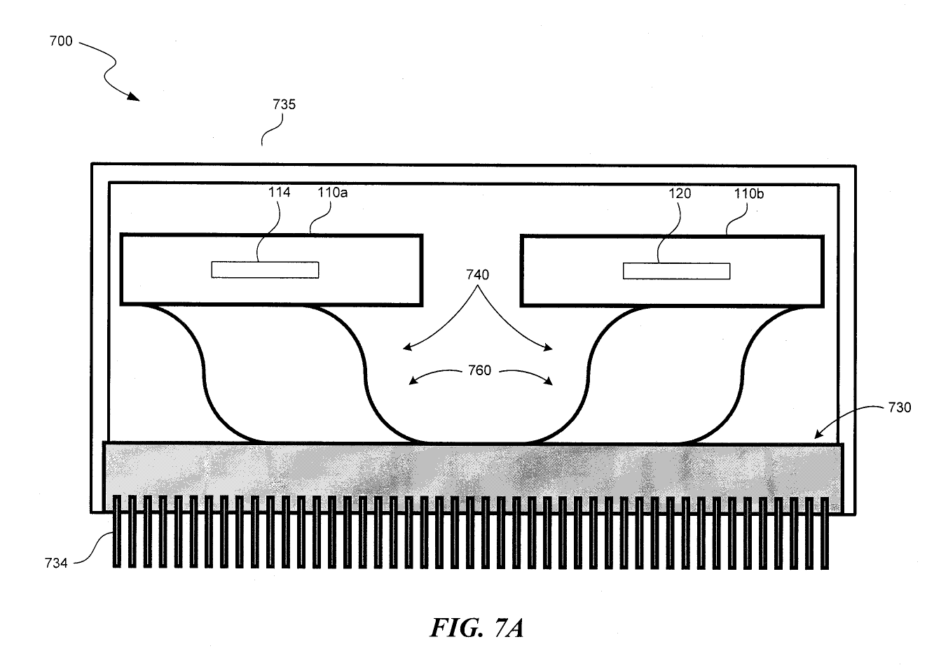

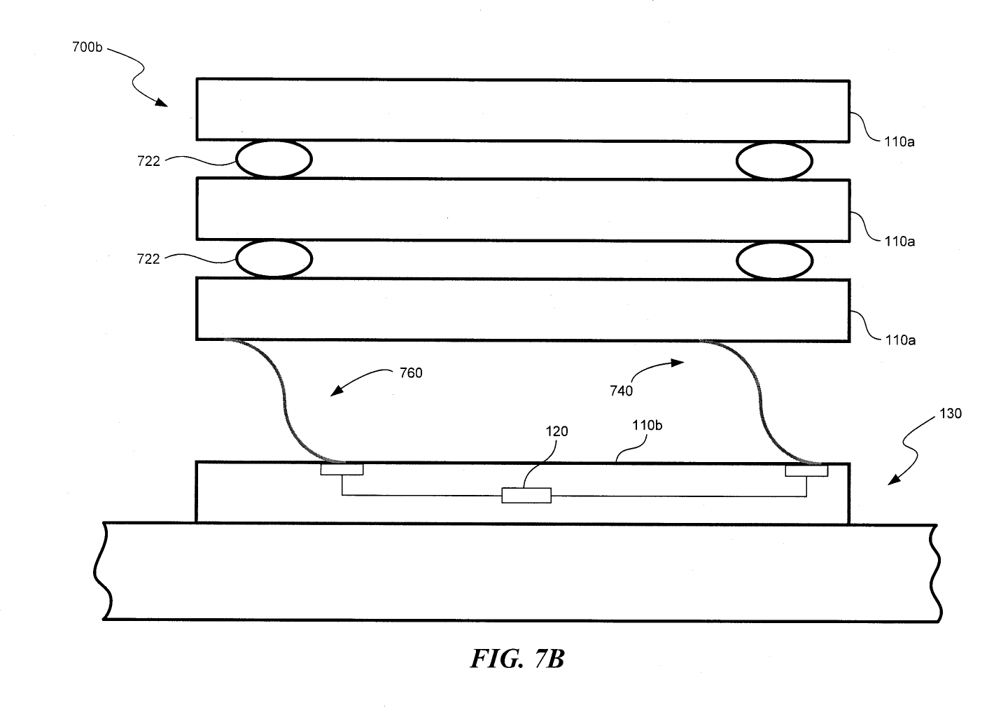

FIG. 7A is a partially schematic, side elevation view of a system 700a configured in accordance with still another embodiment of the disclosure. In one aspect of this embodiment, the system 700a includes a first microelectronic device 110a and a second microelectronic device 110b, each of which is carried via a corresponding flexible connection 760 relative to a support member 730. Accordingly, both the first microelectronic device 110a and the second microelectronic device 110b can move relative to the support member 730. The support member 730 can include contacts 734 (e.g., pins) that provide signal paths to external devices. In a particular aspect of the embodiment shown in FIG. 7A, the system 700a further includes an electrical power generator 740 coupled to each of the first and second microelectronic devices 110a, 110b. In one aspect of this embodiment, the first microelectronic device 110a can include an active element 114 that provides functionalities beyond energy harvesting (e.g., a memory function, a processor function and/or a sensor function), and the second microelectronic device 110b can include a signal conditioning element 120 that conditions power received from the electrical power generators 740 and provides the power back to the first microelectronic device 110a. In other embodiments, the signal conditioning element 120 can be carried by the support member 730 directly, and the second microelectronic device 110b can accordingly carry out functions other than signal conditioning functions. In any of the foregoing embodiments, the system 700a can further include an enclosure 735 positioned around the first and second microelectronic devices 110a, 110b to protect the devices from the external environment. In a particular aspect of this embodiment, the first and second microelectronic devices 110a, 110b can accordingly include a reduced level of such protection. For example, the first and/or second microelectronic devices 110a, 110b can include bare chips rather than packaged chips.

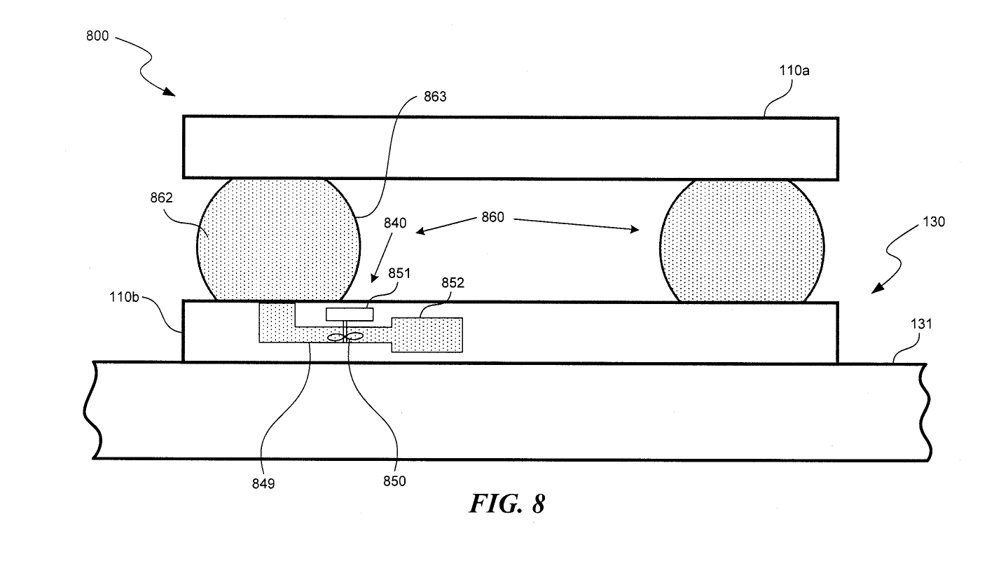

FIG. 7B illustrates another system 700b having multiple, moving microelectronic devices in accordance with another embodiment of the disclosure. In this particular embodiment, the system 700b includes multiple first microelectronic devices 110a, stacked relative to each other and connected to each other via the solder balls or other conductive connectors 722. Each of the first microelectronic devices can provide one or more functions generally similar to those described above (e.g., memory, processor and/or sensor functions), and the support member 130 can facilitate energy harvesting, signal conditioning, and delivery of the energy back to the first microelectronic devices 110a. In other embodiments, one or more of the first microelectronic devices 110a can be replaced with other elements, e.g., a battery that stores power for the microelectronic devices 110a, 110b and/or for other devices. In still further embodiments, the connections between each of the neighboring first microelectronic devices 110a can also include a flexible connection in place of the solder balls. In any of these embodiments, the flexible connection 760 and electrical power generator 740 can have configurations generally similar to any of those discussed above or described below with reference to FIGS. 8-10.

FIG. 8 is a partially schematic, side elevation view of a system 800 that includes a flexible connection 860 and electrical power generator 840 that in turn include a fluid (e.g., a liquid) 862. In a particular aspect of this embodiment, the fluid 862 is contained in a flexible envelope 863 positioned between the first microelectronic device 110a and the support member 130. As the first microelectronic device 110a moves toward the support member 130, the fluid 862 is driven into a flow channel 849 carried by the support member 130. The flow channel 849 directs the fluid 862 to a turbine 850 which powers a generator 851. The fluid then is received in a reservoir 852. As the flexible envelope 863 flexes in the opposite direction (e.g., when the first microelectronic device 110a moves away from the support member 130), the fluid 862 travels from the reservoir 852 back through the flow channel 849 and to the flexible envelope 863. The turbine 850 and the generator 851 can include micromachined elements, and can be configured to harvest energy from fluid 862 traveling in either direction through the flow channel 849. The fluid 862 can be selected for compatibility with integrated circuit structures, and can include de-ionized water, ethanol, isopropyl alcohol or an inert, water immiscible, high specific weight fluid such as perfluorodecalin (C₁₀F₁₈).

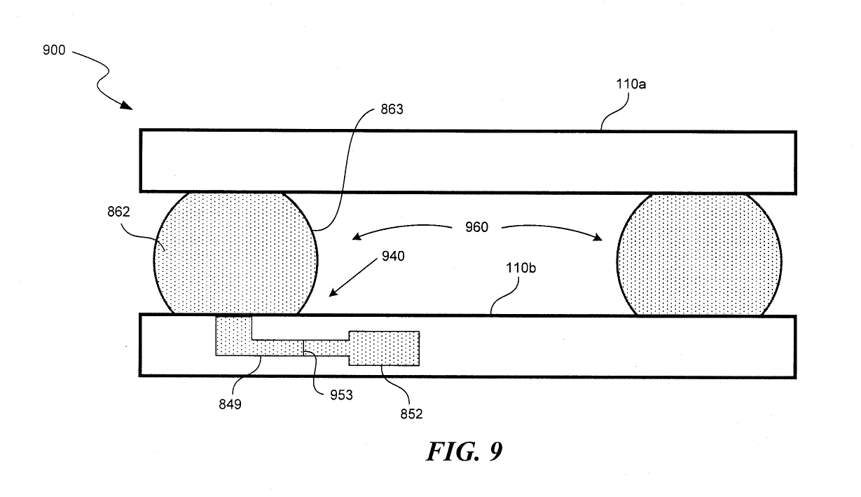

FIG. 9 is a partially schematic illustration of a system 900 having a flexible connection 960 that also includes a fluid 862 carried in an elastic or flexible envelope 863, and coupled to a flow channel 849. In this embodiment, the flow channel 849 directs the fluid 862 through an ionic membrane 953 that separates ions having different charges. Accordingly, the electrical power generator 940 can collect current based on the flow of ions through a return circuit, and can direct this energy back to the first microelectronic device 110a via a suitable conductor (not shown in FIG. 9).

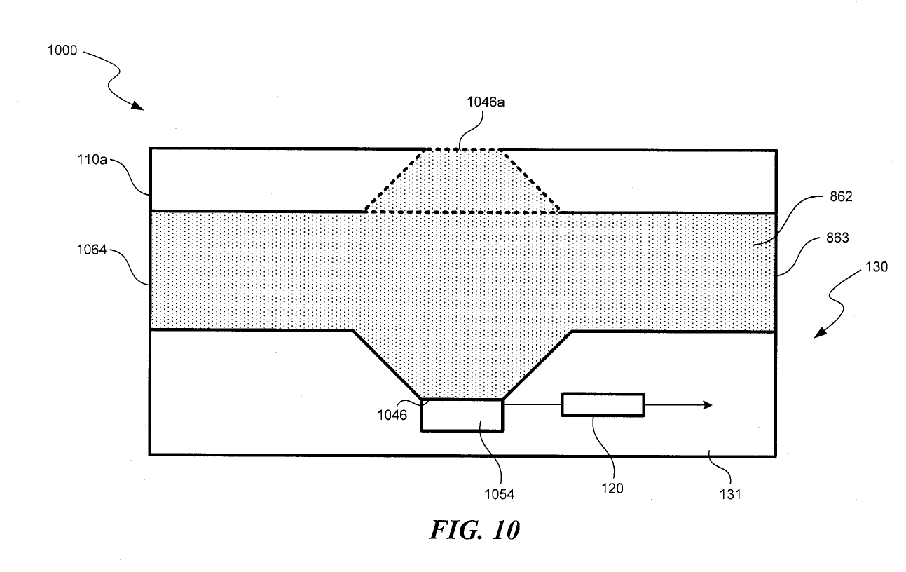

FIG. 10 is a partially schematic, side elevation view of a system 1000 that includes fluid 862 carried in a flexible envelope 863 positioned between the first microelectronic device 110a and the support member 130. The support member 130 can include a piezoelectric member 1046 positioned between the fluid 862 and a cavity 1054. As the first microelectronic device 110a vibrates relative to the support member 130, the piezoelectric member 1046 flexes and generates an electrical current that is conditioned by a signal conditioning element 120 and directed back to the first microelectronic device 110a via one or more conductors (not shown in FIG. 10). In another embodiment shown in dashed lines in FIG. 10, the system 1000 can include a piezoelectric member 1046a carried by the first microelectronic device 110a. In one aspect of this embodiment, the piezoelectric member 1046a is exposed to the environment outside the system 1000 and accordingly, the cavity 1054 can be eliminated. In this embodiment, the first microelectronic device 110a can include its own signal conditioning element 120, or the signal conditioning element can be housed at the support member 130, with appropriate conductors connected between the first microelectronic device 110a and the support member 130.

In either of the embodiments described above with reference to FIG. 10, the piezoelectric member 1046, 1046a can respond to vibrations in a surrounding fluid (e.g., if the system 1000 is immersed in a fluid), in addition to responding to vibrations between the first microelectronic structure 110a and the associated support member. In other embodiments, other systems can also respond to vibrations in the surrounding fluid, which can include a gaseous fluid (e.g., air) or a liquid (e.g., blood or water). For example, the embodiments described above with reference to FIGS. 1-6B and 7B-9 can respond directly to vibrations in the surrounding fluid because such vibrations can cause the first microelectronic device to vibrate relative to the support member. The system shown in FIG. 7B can also respond to such vibrations if the enclosure 735 (or a portion of the enclosure 735) is flexible enough to transmit such vibrations to the elements inside. Accordingly, by capturing vibration energy caused by the surrounding fluid, systems in accordance with embodiments of the presently disclosed technology can further increase the efficiency with which they harvest energy from microelectronic devices.

FIG. 11 is a partially schematic, cross-sectional illustration of a system 1100 that includes a battery 1110 and that harvests kinetic energy in accordance with another embodiment of the present technology. In one aspect of this embodiment, the system 1100 includes a battery package 1101 that in turn includes, in addition to the battery 1110, a support member 1130 that carries or otherwise supports the battery 1110. In particular embodiments, a housing 1135 (e.g., a hermetically sealed enclosure) or other structure encloses the battery 1110 and other elements of the overall system 1100 if such elements are present.

In a particular aspect of the embodiment shown in FIG. 11, the system 1100 can include one or more electrical power generators 1140, three of which are shown schematically together in FIG. 11. Any one or combination of electrical power generators 1140 may be included in any one embodiment of the system 1100. As discussed above with reference to FIG. 1, the one or more electrical power generators 1140 can be carried by the support member 1130, by one or more flexible connections 1160 and/or by the element carried by the flexible connection 1160 (e.g., the battery 1110 shown in FIG. 11). In a particular embodiment, the system 1100 includes first and second flexible connections 1160a, 1160b. The first flexible connection 1160a, in addition to supporting the battery 1110, can provide a path for electrical power to pass to the support member 1130 from the electrical power generators 1140 carried by the first flexible connection 1160a and/or by the battery 1110. The second flexible connection 1160b can provide a path for electrical power to pass to the support member 1130 from the battery 1110 itself. In other embodiments, the flexible connections 1160 can have other arrangements, and/or the system 1100 can transfer power via connections other than the flexible connection 1160. For example, multiple flexible connections 1160 can include electrical power generators 1140. In another example, an individual flexible connection 1160 can include multiple electrical paths to as to transfer electrical power from the electrical power generators 1140 and the battery 1110 via a single structure.

The support member 1130 can be configured to facilitate collecting power from the electrical power generators 1140 and providing both this power and power provided by the battery 1110 to devices external to the battery package 1101. For example, the support member 1130 can include a signal conditioning element 1120 that receives power from the electrical power generators 1140 and conditions it in a manner generally similar to that described above with reference to FIG. 1. Optionally, the signal conditioning element 1120 can also condition power received from the battery 1110, as indicated in dashed lines. The signal conditioning element 1120 can be coupled to one or more active elements 1114, for example, a processor. The active element 1114 can receive power from the signal conditioning element 1120 and (e.g., if the signal conditioning element 1120 does not condition power from the battery 1110) can also receive power directly from the battery 1110 via the second flexible connection 1160b. The active element 1114 can route the power received from the battery 1110 and/or the electrical power generators 1140 to one or more externally accessible electrical connectors 1134 for delivery to any of a variety of power-consuming devices. The signal conditioning element 1120 and/or the active element 1114 can be integrated with the support member 1130, built onto or into the support member 1130, attached to the support member 1130 (e.g., in the form of one or more microelectronic chips), and/or can have other arrangements by which they are carried by the support member 1130.

The active element 1114 can provide other functions typically associated with battery packs, in addition to collecting and routing power from the battery 1110 and the electrical power generators 140. These functions can include providing information about the total capacity of the battery 1110, the available power of the battery 1110, charging information, temperature information, and/or other suitable parameter values. The active element 1114 and/or other elements carried by the support member 1130 or other portions of the system 1100 can also operate to route power from the electrical power generators 1140 to the battery 1110. For example, when the battery 1110 is not actively discharging current via the outside electrical connectors 1134, the active element 1114 and/or other circuit elements can route power collected from the electrical power generator(s) 1140 to the battery 1110 to charge the battery 1110. Accordingly, the battery package 1101 can operate in a self-charging manner or in combination with conventional battery charging operations (e.g., coupling the battery package 1101 into a source of current). In some instances, the power received from the electrical power generator(s) 1140 may be sufficient, by itself, to charge the battery 1110, thus eliminating the need for external charging, and in other instances, conventional charging can supplement or back up the self-charging operation.

In particular embodiments, the battery package 1101 can be sized, shaped, and/or otherwise configured in accordance with existing and/or standard battery package parameters. Accordingly, the battery package 1101 can easily replace or substitute for existing battery packages, while providing the functions described above in addition to those available via conventional battery packages. The self-charging function described above can increase the autonomous operation of any device in which the battery package 1101 is installed.

In conventional energy harvesting arrangements, the moving parts are structures that were specifically designed as inertial masses, with no other functionality. By contrast, one feature of the present technology is that a functional part of the device or the package is the moving part. In particular, a substantial portion of the moving mass is suspended or otherwise carried via non-rigid structures that temporarily store and release energy during vibration, and the moving mass provides a function (e.g., an electrical function) beyond simply being a moving mass. Such functions can include processor functions, memory functions, sensor functions and others.

Another feature of at least some of the foregoing embodiments is a mass that oscillates at a given frequency but with a phase lag relative to the driver. The energy harvester continuously extracts energy from the motion of the mass, which thus experiences a reduced amplitude and increased phase lag. Representative examples include springs as described above, and also liquid drops that act like springs due to surface energy, where the loading of the spring is due to vibration, the unloading of the spring provides energy for the harvesting device.

Multi-chip modules (MCM) are common in microelectronic and micro-transducer production. Typically, the chips in an MCM are rigidly bonded together (e.g., by flip chip packaging); multiple chips may be glued into an electronic device package (e.g., a dual-inline package (DIP)) and connected via wire-bonding; or the chips may be flip-chip bonded via solder bumps. In embodiments of the current technology described above, elastic connections between elements of the overall device or module facilitate the motion and restoring force for the associated energy harvesting devices, and accordingly provide advantages over existing multi-chip modules.

Compared to conventional approaches, in which substantial portions of the valuable silicon “real estate” are dedicated to an inertial mass, the size (volume and/or footprint) of the foregoing energy harvesting devices may be significantly reduced because existing structures serve as the inertial masses. The features added for energy transduction (from motion to electricity) can be patterned by simple lithography, printing methods and/or other existing microelectronic processing techniques. In addition, because the microelectronic devices themselves move relative to the support member, the current technology can harvest power from masses weighing tens of grams and covering areas of one or more square centimeters.

In certain embodiments, some or all the harvested electrical energy is stored by an energy storage device. This energy storage device can be a battery located proximate to the microelectronic device, its packaging, and/or linkages between the microelectronic device and its packaging.

In certain embodiments, the kinetics of the energy harvester (e.g., the flexible connection and/or the electrical power generation element) can be dynamically modified to optimize the power generated by the energy harvester and/or to protect the system from damage. These modifications can include changes of the physical parameters of the microelectronic, its packaging, and/or linkages between the microelectronic and its packaging. These modifications can include changes in the resonant frequency and/or other harmonics of the system, as well as displacement limits and/or force limits. The dynamic modifications can be controlled by the microelectronic device (e.g., if the device includes a microprocessor), by other controlling devices, or via mechanical devices linked to the couplers or connections between elements.

Many of the principles, configuration and/or functions described above with reference to battery packs and microelectronic devices generally can also be applied to accelerometers and, in particular, accelerometers that are of approximately the same scale as microelectronic devices and/or incorporate microelectronic devices. Particular embodiments can be applied to accelerometers that detect and/or measure proper acceleration. Proper acceleration is the rate of change of velocity of an object relative to its inertial frame of reference. For example, an object that is immobile on the Earth's surface has a proper acceleration in the upward direction of approximately 1G, whereas an object in freefall above the Earth's surface has a proper acceleration of zero. The measurement units of proper acceleration are the same as those for acceleration generally, e.g., feet/second² or meters/second².

Accelerometers are generally designed to measure proper acceleration by determining the displacement of a proof mass, sometimes referred to as a sensing mass or seismic mass, on a physical system that operates as a damped spring system. The displacement of the proof mass can be transformed into an electrical signal by a variety of suitable methods, including electromagnetic, electrostatic, piezoelectric, magnetostrictive, and/or optical methods. In a typical accelerometer design, the proper acceleration is measured in orthogonal linear directions and rotational directions. Accordingly, such accelerometers can be used in a wide variety of applications including (a) navigation (using inertial navigation systems) of humans, vehicles such as aircraft, missiles or spacecraft; (b) control and actuation of machines; (c) vibration sensing for buildings, structures, machines and the Earth (e.g., for geophysical monitoring and/or for oil and gas discovery); and/or (d) medical applications, including sports medicine (e.g., in helmets or for improving an athlete's motions) and fall detection for elderly or disabled individuals.

Accelerometers typically use microelectronic devices to process the signals received from the sensor portions of the device and produce signals suitable for an end user. Accelerometers generally have sensing bandwidth limitations. Depending upon the properties of the physical detection and measurement system, a given accelerometer will have limited responses to rapid changes in acceleration occurring above certain high frequencies. The sensing bandwidth generally decreases in proportion to the square root of the proof mass. Generally, the sensing bandwidth limitations of an accelerometer are not significant because the dampened spring system for proper acceleration measurement typically resonates at much higher frequencies than are required for proper acceleration measurements.

However, conventional accelerometers generally suffer from various other types of errors that include position/orientation error (also referred to as noise error), scale factor error, and/or bias error. Errors such as scale factor error and bias error can often be effectively eliminated by properly calibrating the accelerometer. However, position/orientation error may be an inherent element of the physical design of the device, and is often of significant importance for the applications in which the accelerometer operates. In general, the sensitivity of the accelerometer to errors in position and orientation is highly dependent upon the value (e.g., the size) of the proof mass. In particular, the sensitivity generally increases linearly with the value of the proof mass. Accordingly, the larger the proof mass, the more accurate the accelerometer.

One difficulty associated with integrating a proper accelerometer with a microelectronic device is providing a proof mass that is large enough to generate signals with suitable accuracy, without increasing the size of the device significantly. Most current microelectronic-scale accelerometers have proof masses with extremely small values of between approximately 10⁻⁵ to 10⁻⁸ grams. This range of masses is significantly smaller than the proof mass for macro-scale accelerometers, which is typically 1 gram or more. Because the sensitivity of the accelerometer is a linear function of proof mass, microelectronic-scale accelerometers typically suffer from considerably lower sensitivities than macro-scale accelerometers. As a result, while designers would like to include microelectronic-scale accelerometers in many devices, macro-scale devices (e.g., gyroscopes) are still used extensively for high precision inertial navigation systems that require low error and high sensitivity.

FIG. 12A is a partially schematic, cross-sectional illustration of a conventional microelectronic-scale accelerometer system 12. The accelerometer system 12 includes a package 13 that encloses an accelerometer chip 16, which is attached to a proof mass 14 with one or more flexible supports 15. Accordingly, the proof mass 14 can move relative to the accelerometer chip 16 during operation. As the proof mass 14 moves relative to the accelerometer chip 16, one or more transducers 17 detect the motion and generate electrical signals associated with the motion. The accelerometer chip 16 processes the electrical signals and provides corresponding output signals, indicative of acceleration, for use outside the package 13. The output signals can be routed outside the package 13 via one or more wire bonds 18 and corresponding bond pads 19.

FIG. 12B is a partially schematic, cross-sectional illustration of a system 1200 configured in accordance with an embodiment of the present technology. The system 1200 includes an accelerometer 1201 that can detect proper or other types of acceleration. The accelerometer 1201 in turn includes a support member 1230 which supports a first microelectronic device 1210a via one or more flexible connections 1260. The first microelectronic device 1210a can include a microelectronic or semiconductor chip that carries out signal processing and data reduction tasks, e.g., similar to those carried out by a conventional accelerometer chip. In a particular embodiment, the first microelectronic device 1210a can be connected directly to a substrate element 1231 that forms a portion of the support member 1230. In other embodiments, for example an embodiment shown in FIG. 12B, the first microelectronic device 1210a can be connected to a second microelectronic device 1210b, that also forms a portion of the support member 1230. For purposes of illustration, internal features of the first microelectronic device 1210a and the second microelectronic device 1210b are not shown in FIG. 12B. In general, these microelectronic devices can have internal features generally similar to those described above with reference to the corresponding microelectronic devices 110a, 110b shown in FIG. 1. In some embodiments, functions performed by the second microelectronic device 1210b can be performed by elements that are integrated directly into or fabricated directly onto the support member 1230, in a manner generally similar to that described above with reference to FIG. 11.

The first microelectronic device 1210a and/or the second microelectronic device 1210b can have one or more of the following characteristics. These devices can be nano-scale devices (e.g., with a size scale of from approximately tens of angstroms to one micron per side) or micro-scale devices (e.g., with a size scale of from about a few microns to tens of millimeters be side). The devices can take the form of an electronic circuit chips, a multiple-chip module, associated packaging and/or other electronic components including capacitors and batteries, micromechanical components, micro-electro-mechanical components, MEMS devices and/or other suitable structures. The microelectronic devices can be off-the-shelf components and accordingly need not be adapted, retrofitted, and/or otherwise modified to perform the functions described herein.

In any of the foregoing embodiments, the first microelectronic device 1210a moves relative to the support member 1230, and this motion is detected by one or more transducers 1250. In an embodiment shown in FIG. 12B, multiple transducers 1250 are shown as being carried by the first microelectronic device 1210a, the substrate element 1231, and the flexible connections 1260. In other embodiments, the transducers 1250 may be positioned at only a subset of these locations, or can be positioned at other locations. In any of these embodiments, the accelerometer 1201 can include a housing 1235 that surrounds or at least partially surrounds the first microelectronic device 1210a to protect the first microelectronic device 1210a and/or other internal elements of the accelerometer 1201 from the external environment. One or more electrical connectors 1218 (e.g., bond pads, vias, solder balls, wire bonds and/or other suitable devices, alone or in combination) can transmit signals between the accelerometer 1201 and the external environment during operation. The flexible connections 1260 can be used to support the first microelectronic device 1210a relative to the support member 1230, and can also transmit electrical signals from the first microelectronic device to the support member 1230, in a manner generally similar to that described above with reference to FIGS. 1-11.

One feature of an embodiment of the accelerometer 1201 described above with reference to FIG. 12B is that the mass of the first microelectronic device 1210a is typically significantly larger than the mass of the proof mass used in conventional systems, such as the one described above with reference to FIG. 12A. In particular, the mass of the first microelectronic device 1210a can be larger (e.g., multiple orders of magnitude larger) than that of the proof mass described above with reference to FIG. 12A. For example, the mass of the first microelectronic device 1210a can be from about 0.1 grams to about 5 grams, and it can cover an area of tens of square millimeters. In particular embodiments, the first microelectronic device 1210a can be an off-the-shelf device, thus increasing the ease of incorporating the device into the system 1200 and reducing the cost for doing so. In other embodiments, the first microelectronic device 1210a can be specifically manufactured for use in the manner described herein, e.g., to further exploit the features described above. For example, the first microelectronic device 110a can include a cantilever beam along with provisions that allow it to be “inverted” with the end of the beam attached to the support member 1230, with or without a proof mass. In another embodiment, the stiffness of the flexible connections 1260 can be tailored, adjusted and/or selected to account for the increased mess of first microelectronic device relative to a typical proof mass, e.g., to avoid resonant frequencies that may interfere with detecting target acceleration values. An advantage of any of the foregoing arrangements is that the accelerometer 1201 can produce results with significantly higher precision, accuracy, repeatability and/or reliability than those of the system 12 described above with reference to FIG. 12A. At the same time, the overall footprint and/or volume of the accelerometer 1201 can be the same as, on the same order as, or smaller than the corresponding footprint and/or volume of the conventional system described above with reference to FIG. 12A.

FIG. 12C illustrates an accelerometer 1201 configured in accordance with another embodiment of the present technology. In this embodiment, the accelerometer 1201 includes fewer transducers 1250 than are shown in FIG. 12B. In particular, the transducers 1250 may be located only on or carried only by the first microelectronic device 1210a and the support member 1230, but not on or by the flexible connections 1260. In still further embodiments, the transducers 1250 can be located on the second microelectronic device 1210b and can be directly coupled to circuitry within the second microelectronic device 1210b.

FIG. 12D illustrates an accelerometer 1201 configured in accordance with still another embodiment of the present technology. In this embodiment, the mechanical-type flexible connection 1260 described above with reference to FIG. 12B is replaced with a magnetically-based flexible connection 1260 that includes one or more magnets 1280. In particular, one set of magnets 1280a can be carried by the first microelectronic device 1210a, and another set of opposing magnets 1280b can be carried by the support member 1230 and/or the housing 1235. Accordingly, the first microelectronic device 1210a can be magnetically levitated within the housing 1235 without the need for a mechanical support. In this embodiment, electrical signals can be transmitted from the first microelectronic device 1210a to the second microelectronic device 1210b and/or other elements of the support member 1230 the wire bonds and/or RF signals or other wireless communication techniques.

From the foregoing, it will be appreciated that specific embodiments of the technology have been described herein for purposes of illustration, but that various modifications may be made without deviating from the technology. For example, the technology can include devices other than those described above for harvesting electrical energy resulting from vibrational motion (and/or other forms of kinetic energy) between a microelectronic device and a corresponding support member or packaging. In particular embodiments, a battery or other energy storage device can be included as part of the moving mass. In certain embodiments, the present technology can eliminate the need for a battery. In particular embodiments, harvested energy can be provided to devices other than the first microelectronic device, in addition to or in lieu of providing the harvested energy to the first microelectronic device. In certain embodiments, the power harvesting and conditioning function can be performed entirely by the first microelectronic device and the flexible coupling, with the support member simply providing an attachment point for the flexible coupling. For example, the signal conditioning element can be carried by the first microelectronic device rather than the support member.

Certain aspects of the technology described in the context of particular embodiments may be combined or eliminated in other embodiments. For example, the bare chips described above in the context of FIG. 7A can be included in at least some of the other embodiments described herein. Energy harvesting devices described in the context of particular embodiments may be combined with other energy harvesting devices in other embodiments. Further, while advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A battery package, comprising:
a support member;
a battery positioned proximate to the support member;
a flexible connection positioned to support the battery relative to the support member and allow relative movement between the battery and the support member; and
an electrical power generation element carried by at least one of the support member, the battery and the flexible connection, the electrical power generation element being positioned to generate electrical power from the relative movement between the battery and the support member.

2. An accelerometer system, comprising:
a support member;
a microelectronic device positioned proximate to the support member, the microelectronic device including circuitry for providing a signal corresponding to or correlated with acceleration;
a flexible connection positioned to support the battery relative to the support member and allow relative movement between the battery and the support member; and
a transducer carried by at least one of the support member, the microelectronic device and the flexible connection, the transducer being positioned to generate a transducer signal based at least in part on the relative movement between the microelectronic device and the support member, the transducer being operatively coupled to the microelectronic device to transmit the transducer signal to the microelectronic device.

3. A microelectronic device system, comprising:
a semiconductor chip having an active semiconductor element that includes a processor element, a memory element, or both a processor element and a memory element;
a support member;
a flexible connection between the support member and the semiconductor chip positioned to allow the semiconductor chip to move relative to the support member;
a magnet carried by one of the semiconductor chip and the support member;
an electrical coil carried by the other of the semiconductor chip and the support member; and
a signal conditioning element coupled to the electrical coil to condition electrical power generated by movement of the semiconductor chip relative to the support member, wherein the flexible connection includes a conductor coupled between the signal conditioning element and the semiconductor chip to transmit the electrical power to the semiconductor chip.

4. The system of claim 3 wherein the signal conditioning element is carried by the support member.

5. The system of claim 3 wherein the support member includes a printed circuit board.

6. The system of claim 3 wherein the semiconductor chip is a first semiconductor chip, and wherein the support member includes a second semiconductor chip.

7. The system of claim 3 wherein the flexible connection includes a microspring.

8. A microelectronic device system, comprising:
a semiconductor chip having an active semiconductor element;
a support member;
a flexible connection between the support member and the semiconductor chip positioned to allow relative movement between the semiconductor chip and the support member, wherein at least one of the semiconductor chip and the flexible connection includes an electrical power generation element; and
a circuit element coupled to the electrical power generation element to condition electrical power generated by movement of the semiconductor chip relative to the support member.

9. The system of claim 8 wherein the flexible connection includes a conductor coupled between the electrical power generation element and the active semiconductor element to transmit power to the active semiconductor element.

10. The system of claim 8, further comprising an electrical energy storage device coupled to the electrical power generation element to store electrical energy generated by the electrical power generation element.

11. The system of claim 10 wherein the electrical energy storage device includes a battery.

12. The system of claim 8 wherein the electrical power generation element includes a magnet carried by one of the semiconductor chip and the support member, and an electrical coil carried by the other of the semiconductor chip and the support member.

13. The system of claim 8 wherein the electrical power generation element includes an electrostatic device.

14. The system of claim 13 wherein the electrostatic device includes a plurality of capacitor plates.

15. The system of claim 8 wherein the electrical power generation element includes a piezoelectric element positioned to be subjected to a time-varying elastic strain during relative movement between the semiconductor chip and the support member and, in response to the strain, produce a time-varying electric field.

16. The system of claim 8 wherein the electrical power generation element includes a magnetostrictive element and a coil, the magnetostrictive element being positioned to be subjected to a time-varying elastic strain during relative movement between the semiconductor chip and the support member and, in response to the strain, produce a time-varying magnetic field that in turn produces an electrical current in the coil.

17. The system of claim 8 wherein the semiconductor chip is a bare chip.

18. The system of claim 8 wherein the semiconductor chip is a packaged chip.

19. The system of claim 8 wherein the electrical power generation element includes a fluidic element.

20. The system of claim 19 wherein the flexible connection includes a flexible envelope containing a fluid, and wherein the fluidic element includes:
a flow channel in fluid communication with the flexible envelope;
a turbine positioned in the flow channel; and
an electric generator coupled to the turbine.

21. The system of claim 19 wherein the flexible connection includes a flexible envelope containing a fluid, and wherein the fluidic element includes:
a flow channel in fluid communication with the flexible envelope; and
an ionic membrane positioned in the flow channel.

22. The system of claim 19 wherein the flexible connection includes a flexible envelope containing a fluid, and wherein the fluidic element includes:
a piezoelectric element positioned between a cavity and the fluid in the flexible envelope.

23. A method for harvesting kinetic energy from a microelectronic device, comprising:
supporting a semiconductor chip relative to a support member with a flexible connection, the semiconductor chip having an active semiconductor element;
generating electrical power from relative motion between the semiconductor chip and the support member; and
performing an electrically-driven process with the semiconductor chip.

24. The method of claim 23, further comprising conditioning the electrical power.

25. The method of claim 23, further comprising directing the electrical power to the semiconductor chip to perform the electrically-driven process.

26. The method of claim 23 wherein the semiconductor chip is a processor chip, and wherein the electrically-driven process includes a processor function.

27. The method of claim 23 wherein the semiconductor chip is a memory chip, and wherein the electrically-driven process includes a memory function.

28. The method of claim 23 wherein the semiconductor chip is a sensor chip, and wherein the electrically-driven process includes a sensor function.

29. The method of claim 28 wherein the relative motion includes vibrations, and wherein generating electrical power includes generating electrical power in an electromagnetic process in which the vibrations cause relative mechanical movement between a magnet and an electrical coil, which induces a change in magnetic flux that drives an electric current.

30. The method of claim 23 wherein the relative motion includes vibrations, and wherein generating electrical power includes generating electrical power in an electrostatic process in which the vibrations cause relative mechanical movement between charged elements, which induces currents in conductors connected to the charged elements.

31. The method of claim 23 wherein the relative motion includes vibrations, and wherein generating electrical power includes generating electrical power in a piezoelectric process in which the vibrations induce time-varying elastic strain in a piezoelectric material, producing a time-varying electric field in the material, and a corresponding electric current.

32. The method of claim 23 wherein the relative motion includes vibrations, and wherein generating electrical power includes generating electrical power in a magnetostrictive process in which the vibrations induce a time-varying elastic strain in a magnetostrictive material in the presence of an electrical coil, producing a time-varying magnetic field in the magnetostrictive material, and a corresponding electrical current in the coil.

33. The method of claim 23 wherein the relative motion includes vibrations, and wherein generating electrical power includes generating electrical power in a fluidic process in which the vibrations cause relative fluid movements, which are transduced into electric current.

34. A method for harvesting kinetic energy and transducing the kinetic energy into electrical energy for use by a microelectronic device, by:
(a) harvesting the kinetic energy produced by relative motion between the microelectronic device and at least one of a support member and packaging for the microelectronic device, and
(b) transducing the kinetic energy into electrical energy by any one or more of the following processes:
(i) an electromagnetic process, in which the kinetic energy causes relative mechanical movement between a magnet and an electrical coil, which induces a change in magnetic flux that drives a current in the coil;
(ii) an electrostatic process, in which the kinetic energy causes relative mechanical movement between charged elements, which induces currents in wires connected to the charged elements,
(iii) a piezoelectric process, in which the kinetic energy induces time-varying elastic strain in a piezoelectric material, producing a time-varying electric field in the piezoelectric material, and a corresponding electrical current,
(iv) a magnetostrictive process, in which the kinetic energy induces a time-varying elastic strain in a magnetostrictive material in the presence of an electrical coil, producing a time-varying magnetic field in the magnetostrictive material, and a corresponding electrical current in the coil, and
(v) a fluidic process, in which the kinetic energy causes relative fluid movements, which are transduced into electrical current.

35. The method of claim 34 wherein harvesting the kinetic energy includes:
(a) harvesting energy to due relative translational, rotational, or both translation and rotational displacements, and wherein
(b) the relative displacements are between any of the following:
(i) multiple microelectronic devices, and
(ii) packaging components of the microelectronic device.

36. A method for making a microelectronic device, comprising:
connecting (a) a semiconductor chip having an active semiconductor element to (b) a support member, with (c) a flexible connection that allows relative movement between the semiconductor chip and the support member,
providing at least one of the support member and the semiconductor chip with an electrical power generation element; and
connecting a circuit element to the electrical power generation element to condition electrical power generated by relative movement between the semiconductor chip and the support member.

37. The method of claim 36, further comprising:
selecting the flexible connection to produce a resonant frequency for relative motion between the semiconductor chip and the support member that is approximately equal to a vibration frequency in an operating environment for the semiconductor chip.

38. The method of claim 36, further comprising selecting the electrical power generation element to convert vibration energy from relative movement between the semiconductor chip and the support member to electrical energy by any one or more of the following processes:
(i) an electromagnetic process, in which the vibrations cause relative mechanical movement between a magnet and an electrical coil, which induces a change in magnetic flux that drives a current in the coil;
(ii) an electrostatic process, in which the vibrations cause relative mechanical movement between charged elements, which induces currents in wires connected to the charged elements,
(iii) a piezoelectric process, in which the vibrations induce time-varying elastic strain in a piezoelectric material, producing a time-varying electric field in that material, and a corresponding electrical current,
(iv) a magnetostrictive process, in which the vibrations induce a time-varying elastic strain in a magnetostrictive material in the presence of an electrical coil, producing a time-varying magnetic field in that material, and a corresponding electrical current in the coil,
(v) a fluidic process, in which the vibrations cause relative fluid movements, which are transduced into electrical current.

39. A microelectronic system, comprising:
a microelectronic structure;
a battery;
a flexible connection between the microelectronic structure and the battery positioned to allow relative movement between the microelectronic structure and the battery, wherein at least one of the microelectronic structure, the battery and the flexible connection includes an electrical power generation element; and
a circuit element coupled to the electrical power generation element to condition electrical power generated by movement of the semiconductor chip relative to the support member.

40. The system of claim 39 wherein the microelectronic structure includes a semiconductor chip and a support member.

41. The system of claim 39 wherein the electrical power generation element includes a piezoelectric element positioned to be subjected to a time-varying elastic strain during relative movement between the microelectronic structure and the battery and, in response to the strain, produce a time-varying electric field.
